(19) United States
(12) Patent Application Publication
(10) Pub. No.: US 2010/0117184 A1
(43) Pub. Date: May 13, 2010

(54) METHOD OF MANUFACTURING IMAGE SENSOR

(76) Inventor: Chung-Kyung Jung, Anyang-si (KR)

Correspondence Address: SHERR & VAUGHN, PLLC, 620 HERNDON PARKWAY, SUITE 320, HERNDON, VA, 20170, US

(21) Appl. No.: 12/615,757

(22) Filed: Nov. 10, 2009

(30) Foreign Application Priority Data
Nov. 12, 2008 (KR) 10-2008-0112025

(51) Int. Cl. H01L 31/0248; H01L 31/02

(52) U.S. Cl. 257/461; 438/98; 257/E31.11; 257/E31.002

(57) ABSTRACT

A method of manufacturing an image sensor and an image sensor. A method of manufacturing an image sensor may include forming an interlayer dielectric including a metal line on and/or over a semiconductor substrate, forming an image sensing part on and/or over an interlayer dielectric, and/or forming a hard mask in which an opening corresponding to a metal line may be defined on and/or over an image sensing part. A method of manufacturing an image sensor may include performing an etch process to form an auxiliary via hole exposing an inside of an image sensing part, and/or forming a spacer within a auxiliary via hole by an etch byproduct of a hard mask. A method of manufacturing an image sensor may include performing an etch process including a chemical to remove a spacer, and/or etching an image sensing part and/or an interlayer dielectric to form a deep via hole.

The present application claims priority under 35 U.S.C. 119 to Korean Patent Application No. 10-2008-0112025 (filed on Nov. 12, 2008) which is hereby incorporated by reference in its entirety.

### BACKGROUND

Embodiments relate to a method of manufacturing an image sensor.

Image sensors may be semiconductor devices which may convert optical images to electric signals. Image sensors may be classified as a charge coupled device (CCD) image sensor and/or a complementary metal oxide silicon (CMOS) image sensor (CIS). A CIS may include a photodiode region to convert light signals to electrical signals and/or a transistor region to processes converted electrical signals. A photodiode region and/or a transistor region may be horizontally arranged in a semiconductor substrate. Since a photodiode region and a transistor region may be horizontally arranged in a semiconductor substrate in a horizontal-type image sensor, it may not be able to maximize an optical sensing region, for example a fill factor, within a limited area.

To address these drawbacks, attempts may have been made to form a photodiode using amorphous silicon (Si), and/or attempts may have been made to form a readout circuitry in a Si substrate, for example using a method including wafer-to-wafer bonding, and forming a photodiode on and/or over a readout circuitry, which may relate to a three-dimensional (3D) image sensor. A photodiode may be connected with a readout circuitry, for example through a metal line. A patterning process may be needed to form a PN and/or PIN junction on and/or over a photodiode formed on and/or over an interlayer dielectric of a semiconductor substrate using wafer-to-wafer bonding. A wafer may have a thickness of approximately 1.2 μm and may be patterned using an etch process. However, it may be relatively difficult to etch a photodiode using a photoresist process because a wafer may be relatively thick.

Accordingly, there is a need for a method of manufacturing an image sensor and an image sensor that may minimize defects, maximize a fill factor and/or a physical bonding force. There is a need for a method and device which may minimize a size of a via hole, which may maximized a number of pixels and/or which may maximize efficiency of a device.

### SUMMARY

Embodiments relate to a method of manufacturing an image sensor. According to embodiments, a vertical-type image sensing part may be adopted to minimize a size of a via hole to form a PN junction of an image sensing part.

According to embodiments, a method of manufacturing an image sensor may include forming an interlayer dielectric including a metal line on and/or over a semiconductor substrate. In embodiments, a method of manufacturing an image sensor may include forming an image sensing part including a first doped layer and/or a second doped layer which may be stacked on and/or over an interlayer dielectric. In embodiments, a method of manufacturing an image sensor may include forming a hard mask in which an opening corresponding to a metal line may be defined on and/or over an image sensing part.

According to embodiments, a method of manufacturing an image sensor may include performing an etch process using a hard mask as an etch mask to form an auxiliary via hole, which may expose an inside of an image sensing part. In embodiments, a method of manufacturing an image sensor may include forming a spacer in an auxiliary via hole by an etch byproduct of a hard mask when an auxiliary via hole is formed. In embodiments, a method of manufacturing an image sensor may include performing an etch process using a chemical to substantially remove a spacer in an auxiliary via hole.

According to embodiments, a method of manufacturing an image sensor may include a cleaning process. In embodiments, a method of manufacturing an image sensor may include etching an image sensing part disposed at a lower portion of an auxiliary via hole and/or an interlayer dielectric to form a deep via hole, which may expose a metal line.

### DRAWINGS

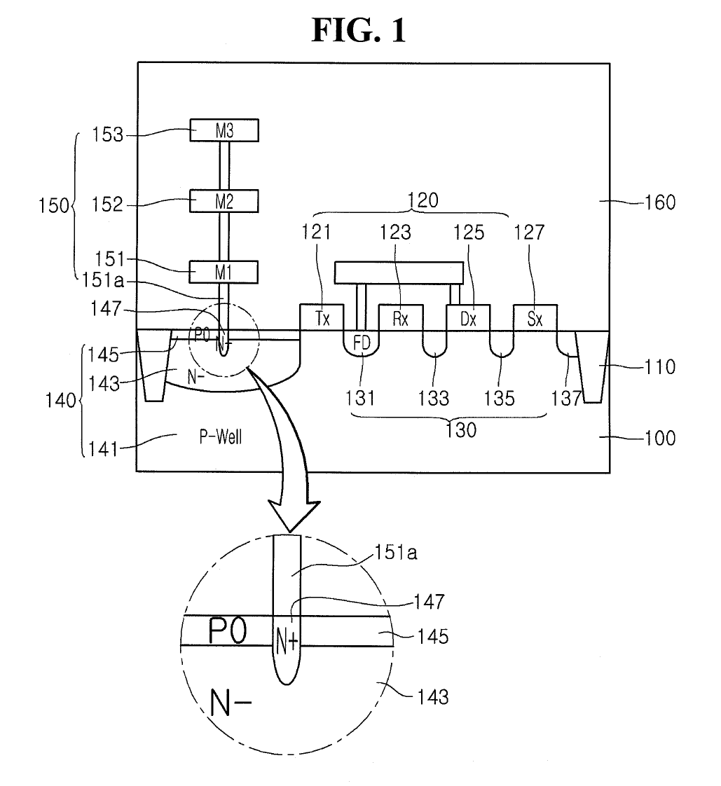

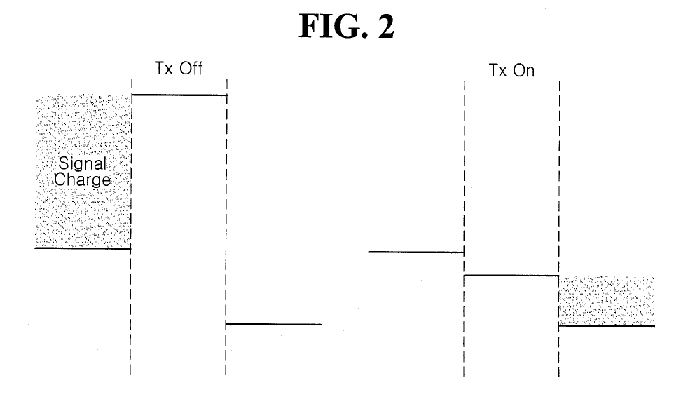

Example FIG. 1 to FIG. 9 are cross-sectional views illustrating a method of manufacturing an image sensor in accordance with embodiments.

### DESCRIPTION

Embodiments relate to a method of manufacturing an image sensor and an image sensor. Embodiments are not limited to a complementary metal oxide silicon (CMOS) image sensor (CIS). Embodiments may include all image sensors in which a photodiode may be required, such as a charge coupled device (CCD) image sensor.

Embodiments relate to a method of manufacturing an image sensor. Referring to example FIG. 1 to FIG. 9, cross-sectional views illustrate a method of manufacturing an image sensor in accordance with embodiments. Referring to FIG. 1, metal line 150 and/or interlayer dielectric 160 may be formed on and/or over semiconductor substrate 100 including readout circuitry 120. According to embodiments, semiconductor substrate 100 may include a single crystalline and/or polycrystalline silicon substrate. In embodiments, semiconductor substrate 100 may include a substrate doped with p-type impurities and/or n-type impurities.

According to embodiments, device isolation layer 110 may be formed on and/or over semiconductor substrate 100 which may define an active region. In embodiments, readout circuitry 120 may include a transistor and may be formed on and/or over an active region. In embodiments, readout circuitry 120 may include transfer transistor (Tx) 121, reset transistor (Rx) 123, drive transistor (Dx) 125 and/or select transistor (Sx) 127. In embodiments, ion implantation region 130 may be formed and may include floating diffusion region (FD) 131 and/or source/drain regions 133, 135, and/or 137 for each transistor. In embodiments, readout circuitry 120 may be applicable to a 3Tr and/or 5Tr structure.

According to embodiments, forming readout circuitry 120 on and/or over semiconductor substrate 100 may include forming electrical junction region 140 on and/or over semiconductor substrate 100 and/or forming first conductive type connection region 147 connected to metal line 150 on and/or over electrical junction region 140. In embodiments, electrical junction region 140 may be a PN junction 140, but embodiments are not limited thereto. In embodiments, electrical junction region 140 may include first conductive type ion implantation layer 143 formed on and/or over second conductive type well 141 and/or a second conductive type epitaxial layer. In embodiments, second conductive type ion implantation layer 145 may be formed on and/or over first conductive type ion implantation layer 143. In embodiments, PN junction 140 may include a P0(145)/N− (143)/P−(141) junction, for example as illustrated in FIG. 1, but embodiments are not limited thereto. In embodiments, semiconductor substrate 100 may be doped with a second conductive type impurity, but embodiments are not limited thereto.

According to embodiments, it may be possible to substantially fully dump photo charges by designing an image sensor such that a potential difference may exist between a source and a drain formed at both ends of the Tx 121. In embodiments, photo charges generated on and/or over a photodiode may be dumped into a floating diffusion region to maximize sensitivity of an output image. In embodiments, since electrical junction region 140 may be formed on and/or over semiconductor substrate 100 including first readout circuitry 120 to generate a potential difference between a source and a drain formed at both ends of Tx 121, it may be possible to substantially fully dump photo charges. In embodiments, unlike image sensor technology where a photodiode may be connected to a N+ junction, embodiments may substantially prevent a saturation and/or sensitivity from being minimized.

According to embodiments, first conductive type connection region 147 may be formed between a photodiode and readout circuitry 120 to maximize movement of photo charges, thereby minimizing a source of dark current and/or substantially preventing saturation and/or sensitivity from being lowered. In embodiments, N+ doped region 147 may be formed on and/or over a surface of P0/N−/P− junction 140 as first conductive type connection region 147 for an ohmic contact. In embodiments, N+ doped region 147 may be formed to penetrate P0 145 and/or contact the N− junction 143.

According to embodiments, a possibility that first conductive type connection region 147 may act as a leakage source may be minimized. In embodiments, a width of first conductive type connection region 147 may be minimized. In embodiments, first metal contact 151a may be etched and a plug implant may be performed, but embodiments are not limited thereto. In embodiments, an ion implantation pattern may be formed, and first conductive type connection region 147 may be formed using an ion implantation pattern as an ion implantation mask. In embodiments, N+ doping region may be locally performed on and/or over a contact formation portion and may minimize a dark signal and/or maximize forming an ohmic contact.

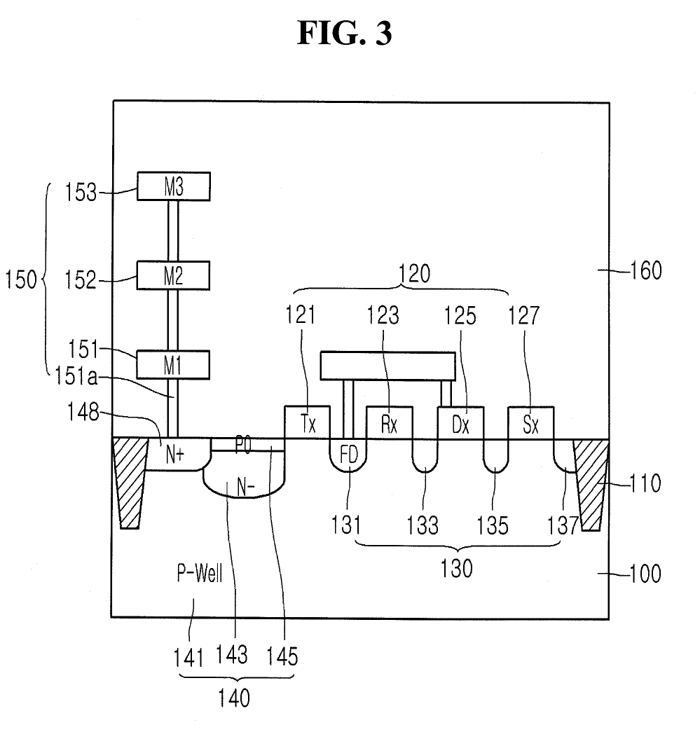

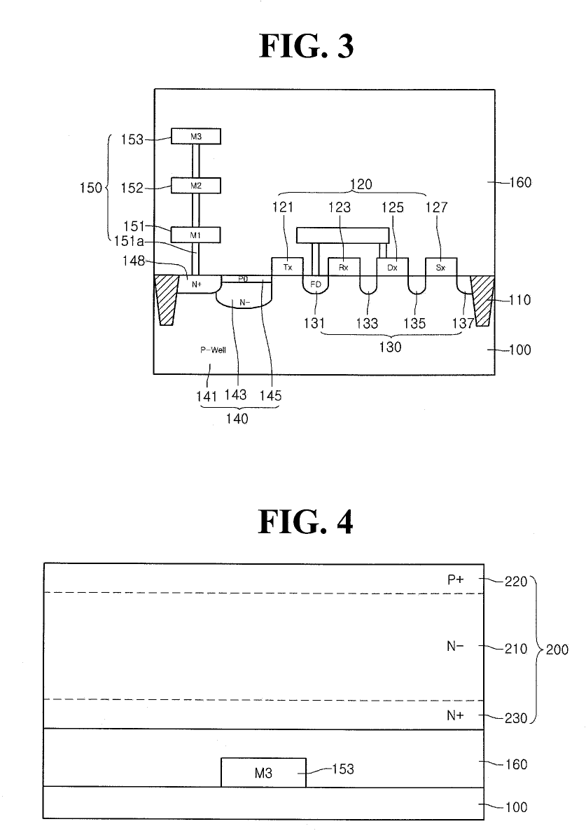

In the case where an entire region of source of Tx 121 is doped with N+ impurities, a dark signal may increase due to Si surface dangling bond. Referring to FIG. 3, a structure of a readout circuitry is illustrated. According to embodiments, first conductive type connection region 148 may be formed on and/or over a side of electrical junction region 140. In embodiments, N+ connection region 148 may be formed on and/or over P0/N−/P− junction 140 for an ohmic contact. N+ connection region 148 and/or first metal contact (M1C) 151a may operate as a leakage source since in operation, a reverse bias may be applied to P0/N−/P− junction 140 to generate an electric field (EF) on and/or over a surface of the Si substrate. A crystal defect generated in an EF during formation of a contact may act as a leakage source. In the case where N+ connection region 148 may be formed on and/or over a surface of P0/N−/P− junction 140, an additional electric field may be generated by N+/P0 junction 148/145, which may also act as the leakage source.

According to embodiments, a doping process may not be performed into P0 layer, a first contact plug may be formed on and/or over an active region including N+ connection region 147, and/or a first contact plug may be connected to N− junction 143. In embodiments, an electric field may not be substantially generated on and/or over a surface of semiconductor substrate 100, for example to minimize a dark current of a 3-D integrated CIS.

Referring back to FIG. 1, interlayer dielectric 160 and/or metal line 150 may be formed on and/or over semiconductor substrate 100. According to embodiments, metal line 150 may include first metal contact 151a, first metal (M1) 151, second metal (M2) 152 and/or third metal (M3) 153, but embodiments are not limited thereto. In embodiments, M3 153 may be formed, and a dielectric may be deposited such that M3 153 may not be substantially exposed. In embodiments, a planarization process may be performed to form interlayer dielectric 160. In embodiments, a surface of interlayer dielectric 160 having a substantially uniform surface profile may be exposed to semiconductor substrate 100.

Referring to FIG. 4, image sensing part 200 may be formed on and/or over interlayer dielectric 160. According to embodiments, image sensing part 200 may have a PN junction diode structure including first doped layer (N−) 210 and/or second doped layer (P+) 220. In embodiments, ohmic contact layer (N+) 230 may be formed below first doped layer 210 in and/or over image sensing part 200. In embodiments, since M3 153 of metal line 150 illustrated in FIG. 4 and/or interlayer dielectric 160 may correspond to portions of metal line 150 and/or interlayer dielectric 160 illustrated in FIG. 1, readout circuitry 120 and/or a portion of metal line 150 may be omitted for illustration.

According to embodiments, image sensing part 200 may include a structure in which N-type impurities (N−) and/or P-type impurities (P+) are ion-implanted, for example sequentially, into a p-type carrier substrate, having for example a crystalline structure, to form a stacked structure of first doped layer 210 and/or second doped layer 220. In embodiments, high-concentration n-type impurities (N+) may be ion-implanted into a bottom surface of first doped layer 210 to form ohmic contact layer 230. In embodiments, ohmic contact layer 230 may minimize a contact resistance between image sensing part 200 and metal line 150. In embodiments, first doped layer 210 may be wider than second doped layer 220. In embodiments, a depletion region may be expanded to maximize a production of photoelectrons.

According to embodiments, ohmic contact layer 230 of a carrier substrate may be disposed on and/or over interlayer dielectric 160. In embodiments, a bonding process may be performed to couple semiconductor substrate 100 to a carrier substrate. In embodiments, a carrier substrate may include a hydrogen layer which may be formed to expose image sensing part 200 bonded on and/or over interlayer dielectric 160 and may be removed, for example by a cleaving process to expose second doped layer 220. In embodiments, image sensing part 200 may have a height between approximately 1.0 μm and 1.5 μm. In embodiments, image sensing part 200 may have a height of approximately 1.2 μm. In embodiments, a depth from a top surface of image sensing part 200 to a bottom surface may relate to a first depth D1.

According to embodiments, since semiconductor substrate 100 including readout circuitry 120 and/or image sensing part 200 may be formed by wafer-to-wafer bonding, defects may be minimized. In embodiments, image sensing part 200 may be formed on and/or over readout circuitry 120 to increase a fill factor. In embodiments, since image sensing part 200 may be bonded to interlayer dielectric 160 which may have a substantially uniform surface profile, a physical bonding force may be maximized. In embodiments, image sensing part 200 may include a PN junction, but embodiments are not limited thereto. In embodiments, image sensing part 200 may include a PIN junction.

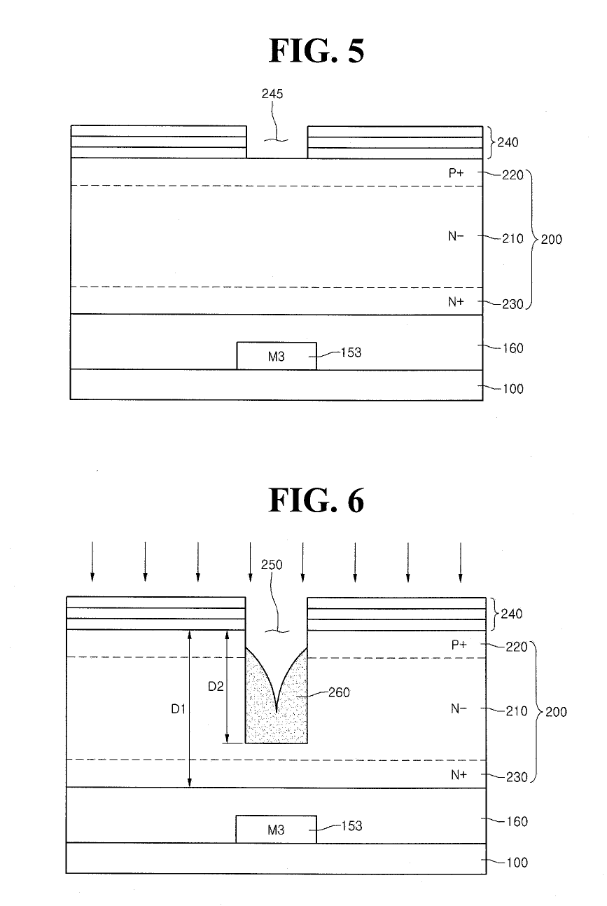

Referring to FIG. 5, hard mask 240 may include opening 245 and may be formed on and/or over image sensing part 200. According to embodiments, hard mask 240 may be formed to expose a surface of image sensing part 200 corresponding to the M3 153. In embodiments, a hard mask may include a triplex structure, for example including an oxide layer-nitride layer-oxide (ONO) layer. In embodiments, hard mask 240 may be used to etch image sensing part 200 and may include a dielectric, since it may be relatively difficult to etch image sensing part 200 using a photoresist, for example where image sensing part 200 includes a first depth D1. In embodiments, hard mask 240 may include an ONO structure and/or may have a high etch selectivity with respect to a Si wafer. In embodiments, image sensing part 200 may be selectively etched.

According to embodiments, a first oxide layer, a nitride layer and/or a second oxide layer may be sequentially deposited on and/or over image sensing part 200 to form a hard mask layer having an ONO structure. In embodiments, a photoresist pattern may be formed which may expose a hard mask layer corresponding to M3 153. In embodiments, an etch process may be performed to form hard mask 240, which may expose image sensing part 200 corresponding to the M3 153. In embodiments, opening 245 of hard mask 240 may be patterned to include a diameter of less than approximately 0.7 μm. In embodiments, an opening of a photoresist pattern may be patterned with a diameter between approximately 0.4 μm and 0.7 μm. In embodiments, an etch process may be performed on and/or over a hard mask layer to form opening 245 of hard mask 240, or example having a diameter between approximately 0.4 μm and 0.7 μm.

Referring to FIG. 6, auxiliary via hole 250 may be formed on and/or over image sensing part 200. According to embodiments, an etch process may be performed using hard mask 240 as an etch mask to form auxiliary via hole 250. In embodiments, a reactive ion etch process may be performed to form auxiliary via hole 250 of image sensing part 200. In embodiments, auxiliary via hole 250 may include a diameter between approximately 0.4 μm and 0.7 μm, which may be substantially equal to that of opening 245 of hard mask 240. In embodiments, auxiliary via hole 250 may include a second depth D2 which may be less than first depth D1. In embodiments, second depth D2 of auxiliary via hole 250 may range between approximately 0.5 μm and 0.8 μm.

According to embodiments, auxiliary via hole 250 may be formed on and/or over image sensing part 200. In embodiments, spacer 260 may be formed on and/or over a sidewall of auxiliary via hole 250. In embodiments, when image sensing part 200 is etched using hard mask 240, a polymer that may be an etch byproduct may be generated. In embodiments, opening 245 may include a relatively small diameter, and a polymer may be formed including a spacer structure inside auxiliary via hole 250 when image sensing part 200 may be etched, for example up to a middle region thereof. In embodiments, it may not be possible to further etch image sensing part 200 when spacer 260 is formed inside auxiliary via hole 250. In embodiments, spacer 260 may be an etch byproduct and may have a junction structure of C-H-O. In embodiments, an etch process may be performed to substantially remove spacer 260 formed on and/or over a sidewall of auxiliary via hole 250, which may expose M3 153.

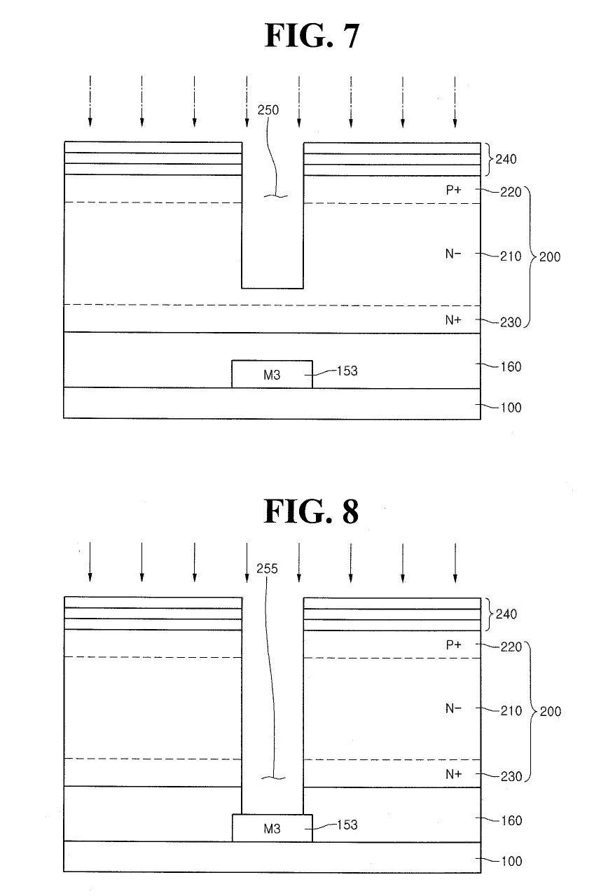

Referring to FIG. 7, spacer 260 formed inside auxiliary via hole 250 may be removed. According to embodiments, a wet etch process may include a chemical and may be performed to substantially remove spacer 260. In embodiments, spacer 260 may be removed using a diluted hydrogen fluoride (DHF) and/or a buffered hydrogen fluoride (BHF) chemical. In embodiments, to remove spacer 260 including a thickness between approximately 5 nm and 20 nm by etching a material of spacer 260 as a target material, a DHF chemical and/or deionized (DI) water may be provided. In embodiments, DI water and a DHF chemical may include a concentration ratio between approximately 100:1 and 200:1. In embodiments, an etch process may be performed between approximately 50 and 300 seconds, for example using DI water and DHF chemical having a concentration ratio between approximately 100:1 and 200:1.

According to embodiments, particles may remain after spacer 260 may be removed. In embodiments, a cleaning process may be performed on and/or over auxiliary via hole 250. In embodiments, a cleaning process may be performed using mega sonic to remove remaining particles by vibrating image sensing part 200 including auxiliary via hole 250. In embodiments, particles of auxiliary via hole 250 may be substantially removed by a cleaning process using a mega sonic. In embodiments, spacer 260 within auxiliary via hole 250 may be substantially removed using an etching chemical, and a sidewall and/or a bottom surface of auxiliary via hole 250 may be exposed. In embodiments, a cleaning process using mega sonic may be performed, and particles may not substantially remain in auxiliary via hole 250.

Referring to FIG. 8, deep via hole 255 may be formed and may pass through image sensing part 200 and/or interlayer dielectric 160 to expose M3 153. In embodiments, a reactive ion etch process may be performed using hard mask 240 and/or auxiliary via hole 250 as masks to etch image sensing part 200 disposed at a lower portion of auxiliary via hole 250 and/or interlayer dielectric 160. In embodiments, deep via hole 255 may be formed. In embodiments, deep via hole 255 may include a diameter between approximately 0.4 μm and 0.7 μm.

According to embodiments, auxiliary via hole 250 may be formed using hard mask 240. In embodiments, an etch process including a chemical may be performed to substantially remove spacer 260 within auxiliary via hole 250. In embodiments, image sensing part 200 disposed at a lower portion of auxiliary via hole 250 may be etched to form deep via hole 255 which may include a diameter between approximately 0.4 μm and 0.7 μm. In embodiments, a hole including a diameter between approximately 0.4 μm and 0.7 μm may be formed in a unit pixel of image sensing part 200 which may include a depth of approximately 0.2 μm. In embodiments, a maximized number of pixels may be realized within a wafer having substantially the same size. In embodiments, efficiency of a device may be maximized. In embodiments, deep via hole 255 may include a diameter between approximately 0.4 μm and 0.7 μm, but embodiments are not limited thereto. In embodiments, deep via hole 255 may include a diameter of less than approximately 0.4 μm.

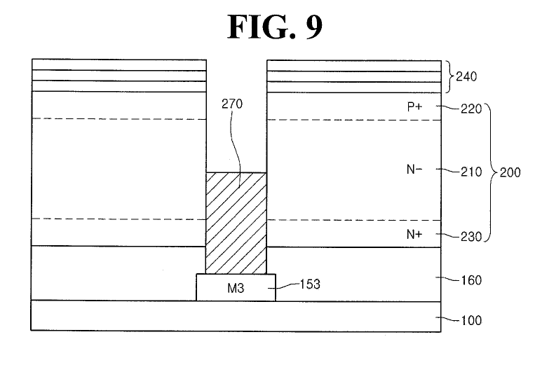

Referring to FIG. 9, contact plug 270 may be formed inside deep via hole 255. According to embodiments, contact plug 270 may be formed inside deep via hole 255 to electrically connect first doped layer 210 and M3 153. In embodiments, contact plug 270 may include a metal such as tungsten (W), copper (Cu) and/or aluminum (Al). In embodiments, a barrier layer may be formed between deep via hole 255 and contact plug 270.

According to embodiments, a pixel separation layer may be formed according to readout circuitry 120 to separate image sensing part 200 for each unit pixel. In embodiments, an upper electrode, a color filter and/or a micro lens may be formed on and/or over image sensing part 200. In embodiments, an image sensing part may be formed on and/or over readout circuitry to maximize a fill factor. In embodiments, a via hole may form a contact connecting an image sensing part to a metal line may be formed with a relatively fine pattern, and may maximize image characteristics. In embodiments, a via hole include a diameter of less than approximately 0.7 μm may be formed in a pixel having a thickness of approximately 1.75 μm. In embodiments, a light receiving region may be relatively substantially expanded within a unit pixel having a limited size and/or may maximize yield of an image sensor. In embodiments, an oxide layer may be used as a hard mask to form a via hole, minimizing a void from occurring.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming an interlayer dielectric including a metal line over a semiconductor substrate;
forming an image sensing part including a first doped layer and a second doped layer over said interlayer dielectric;
forming a hard mask including an opening corresponding to said metal line over said image sensing part;
performing an etch process using said hard mask as an etch mask to form an auxiliary via hole exposing an inside of said image sensing part, wherein a spacer is formed within said auxiliary via hole comprising an etch byproduct when said auxiliary via hole is formed;
performing an etch process including a chemical to substantially remove the spacer; and
etching said image sensing part disposed at a lower portion of said auxiliary via hole and said interlayer dielectric to form a deep via hole exposing at least a portion of said metal line.

2. The method of claim 1, wherein at least one of said auxiliary via hole and said deep via hole are formed comprising a reactive ion etch process.

3. The method of claim 1, wherein said etch byproduct is accumulated to form the spacer.

4. The method of claim 1, wherein the spacer is substantially removed comprising a wet etch process including at least one of a diluted hydrogen fluoride and a buffered hydrogen fluoride chemical.

5. The method of claim 1, wherein substantially removing the spacer comprises a mixture of deionized water and diluted hydrogen fluoride at a concentration ratio between approximately 100:1 and 200:1 for between approximately 50 seconds and 300 seconds.

6. The method of claim 1, comprising performing a cleaning process to substantially remove particles including vibrating said image sensing part having said auxiliary via hole using mega sonic after the spacer is removed.

7. The method of claim 1, wherein said hard mask comprises a triplex structure including at least one of a oxide layer and a nitride layer.

8. The method of claim 1, wherein said opening of said hard mask comprises a diameter between approximately 0.4 μm and 0.7 μm, and said deep via hole comprises substantially the same diameter as the opening.

9. The method of claim 1, comprising forming a contact plug within said deep via hole.

10. The method of claim 9, wherein said contact plug contacts said first doped layer and is spaced from said second doped layer.

11. An apparatus comprising:
an interlayer dielectric including a metal line over a semiconductor substrate;
an image sensing part including a first doped layer and a second doped layer over said interlayer dielectric;
a hard mask including an opening corresponding to said metal line over said image sensing part;
an auxiliary via hole exposing an inside of said image sensing part comprising a spacer including an etch byproduct, wherein said spacer is formed when said auxiliary via hole is formed and is configured to be substantially removed by an etch process comprising a chemical; and
a deep via hole exposing at least a portion of said metal line when the spacer is substantially removed.

12. The apparatus of claim 11, wherein said etch byproduct is accumulated to form the spacer.

13. The apparatus of claim 11, wherein said spacer is configured to be substantially removed comprising a wet etch process including at least one of a diluted hydrogen fluoride and a buffered hydrogen fluoride chemical.

14. The apparatus of claim 11, wherein said image sensing part having said auxiliary via hole is configured to be cleaned by a cleaning process to substantially remove particles using mega sonic.

15. The apparatus of claim 11, wherein said hard mask comprises a triplex structure including at least one of a oxide layer and a nitride layer.

16. The apparatus of claim 11, wherein said deep via hole comprises substantially the same diameter as the opening of said hard mask.

17. The apparatus of claim 11, wherein said deep via hole comprises a diameter between approximately 0.4 μm and 0.7 μm.

18. The apparatus of claim 11, where said deep via hole comprises a diameter less than approximately 0.4 μm.

19. The apparatus of claim 11, wherein said deep via hole comprises a diameter of less than approximately 0.7 μm and is formed in a pixel having a thickness of approximately 1.75 μm.

20. The apparatus of claim 11, comprising a contact plug within said deep via hole.
